(19) United States
(12) Patent Application Publication
(10) Pub. No.: US 2015/0256164 A1
(43) Pub. Date: Sep. 10, 2015

(54) TIMING MEASURING CIRCUIT

(71) Applicant: KABUSHIKI KAISHA TOSHIBA, Minato-ku (JP)

(72) Inventors: Yasushi EBATO, Kawasaki (JP); Nariyuki FUKUDA, Kawasaki (JP); Kazuhito HOSAKA, Kawasaki (JP); Isao OOIGAWA, Kawasaki (JP); Takeshi YAMAGUCHI, Kawasaki (JP); Mamoru ISHIDA, Kawasaki (JP); Eiji BAN, Kawasaki (JP); Kazumi HAYASHIDA, Kawasaki (JP)

(73) Assignee: KABUSHIKI KAISHA TOSHIBA, Minato-ku (JP)

(21) Appl. No.: 14/475,625

(22) Filed: Sep. 3, 2014

Related U.S. Application Data
(60) Provisional application No. 61/949,749, filed on Mar. 7, 2014.

(51) Int. Cl. H03K 5/13

(52) U.S. Cl. CPC H03K 5/13; H03K 2005/00013

(57) ABSTRACT

According to one embodiment, a timing measuring circuit is provided with N (N is an integer of 2 or more) delay circuits and a comparison circuit. The N delay circuits delay a reference signal by different delay times. The comparison circuit outputs N timing adjustment values based on results of comparison between the reference signal and N output signals from the delay circuits.

### CROSS-REFERENCE TO RELATED APPLICATION

This application is based upon and claims the benefit of priority from Provisional Patent Application No. 61/949749, filed on Mar. 7, 2014; the entire contents of which are incorporated herein by reference.

### FIELD

Embodiments described herein relate generally to a timing measuring circuit.

### BACKGROUND

In a semiconductor integrated circuit, variations in operation timing occur due to manufacturing variations. To deal with the case where there is no margin in timing specifications of a semiconductor integrated circuit, there is a semiconductor integrated circuit in which a test circuit such as an inverter chain is embedded so that a timing adjustment is made by blowing a fuse according to a delay time of the test circuit.

### BRIEF DESCRIPTION OF THE DRAWINGS

FIG. 1 is a block diagram of a memory system configuration to which a timing measuring circuit according to a first embodiment is applied;

FIG. 2 is a block diagram of a configuration example of the timing measuring circuit according to the first embodiment;

FIG. 3A is a timing chart illustrating operations of the timing measuring circuit under a center condition, FIG. 3B is a timing chart illustrating operations of the timing measuring circuit under a fast condition, and FIG. 3C is a timing chart illustrating operations of the timing measuring circuit under a slow condition;

FIG. 4 is a diagram of a truth-value table of outputs from the timing measuring circuit illustrated in FIG. 2;

FIG. 5 is a block diagram of a configuration example of a timing measuring circuit according to a second embodiment;

FIG. 6 is a block diagram of a memory system configuration to which a timing measuring circuit according to a third embodiment is applied; and

FIG. 7 is a block diagram of a memory system configuration to which a timing measuring circuit according to a fourth embodiment is applied.

### DETAILED DESCRIPTION

In general, according to one embodiment, a timing measuring circuit is provided with N (N is an integer of 2 or more) delay circuits and a comparison circuit. The N delay circuits delay a reference signal by different delay times. The comparison circuit outputs N timing adjustment values based on results of comparison between the reference signal and N output signals from the delay circuits.

Exemplary embodiments of a timing measuring circuit will be explained below in detail with reference to the accompanying drawings. In addition, the present invention is not limited to the following embodiments.

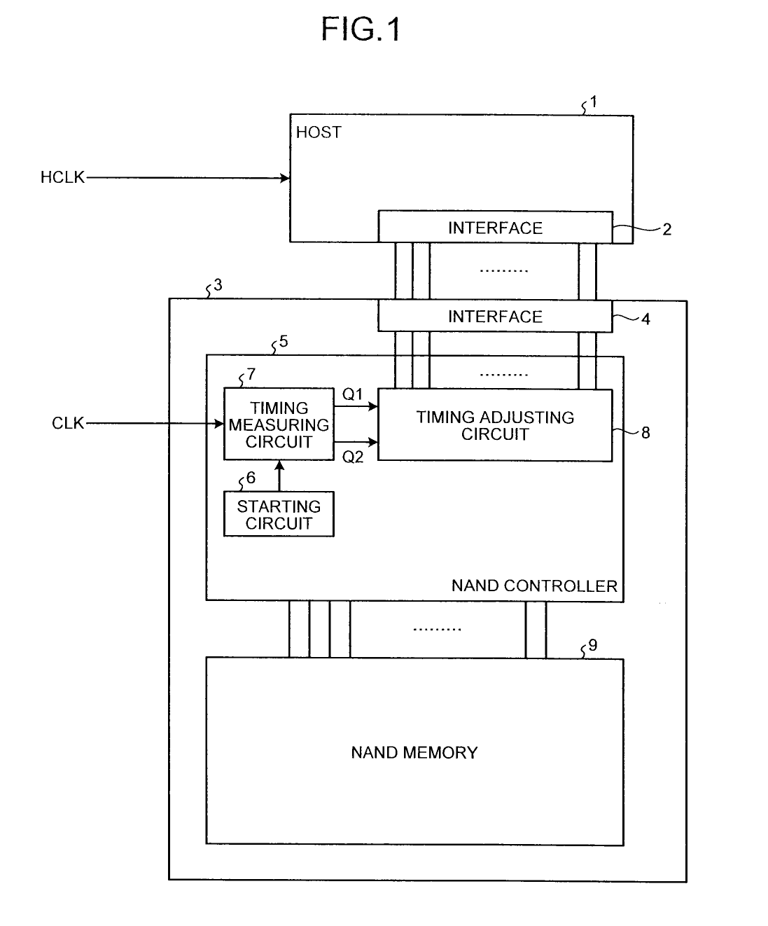

FIG. 1 is a block diagram of a memory system configuration to which a timing measuring circuit according to a first embodiment is applied. Incidentally, in the example of FIG. 1, an NAND memory is used in a memory system.

Referring to FIG. 1, the memory system includes a host 1, an NAND controller 5, and an NAND memory 9. The host 1 is given a host clock HCLK, and the host 1 is capable of operating according to the host clock HCLK. The host 1 also includes an interface 2 that communicates with the NAND controller 5. In addition, the host 1 may be a personal computer that provides instructions to the NAND controller 5, or may be a processor.

The NAND controller 5 can perform drive control on the NAND memory 9. Drive control on the NAND memory 9 includes reading/writing control on the NAND memory 9, block selection, error correction, wear leveling, and the like. The NAND controller 5 is given an external clock CLK, and the NAND controller 5 can operate according to the external clock CLK. The NAND controller 5 and the NAND memory 9 are included in a package 3, and the package 3 is provided with an interface 4 that communicates with the host 1. In addition, the package 3 may constitute a memory card, or may constitute a multi-media card such as an eMMC. Signals exchanged in the NAND controller 5 include data signals, data strobe signals, read enable signals, write enable signals, chip enable signals, command latch enable signals, address latch enable signals, write-protect signals, and ready/busy signals.

The NAND controller 5 is provided with a starting circuit 6, a timing measuring circuit 7, and a timing adjusting circuit 8. The starting circuit 6 is capable of starting the timing measuring circuit 7. The starting circuit 6 may be configured to start the timing measuring circuit 7 at startup of the NAND controller 5 or start the timing measuring circuit 7 on a regular basis at startup of the NAND controller 5. The timing measuring circuit 7 can output timing adjustment values Q1 and Q2 according to variations in timing occurring at the NAND controller 5. The timing measuring circuit 7 may generate the timing adjustment values Q1 and Q2 based on a delay time of the external clock CLK. The timing adjusting circuit 8 can make timing adjustments such that signals treated by the NAND controller 5 fall within timing specifications. For example, the timing adjusting circuit 8 can make timing adjustments such that setup time and hold time of data signals fall within the timing specifications.

Then, a signal output from the host 1 is input into the NAND controller 5 via the interfaces 2 and 4. At that time, the timing adjusting circuit 8 makes a timing adjustment to the signal output from the host 1 and then the NAND controller 5 sends the signal to the NAND memory 9.

When the timing measuring circuit 7 is started by the starting circuit 6, the timing measuring circuit 7 measures delay times of the external clock CLK to determine variations in timing of the signal output from the host 1, and outputs the timing adjustment values Q1 and Q2 to the timing adjusting circuit 8. Then, the timing adjusting circuit 8 adjusts the delay time of the signal exchanged in the NAND controller 5 based on the timing adjustment signals Q1 and Q2, thereby adjusting the timing of the signal exchanged in the NAND controller 5.

By making timing adjustments at the timing adjusting circuit 8, even when variations occur in operation timing due to manufacturing variations of the NAND controller 5, it is possible to increase a margin of timing specifications of the NAND controller 5.

In addition, by making timing measurements at the timing measuring circuit, there is no need to measure timing characteristics by a test circuit such as an inverter chain included in the NAND controller and blow a fuse according to results of the measurement by the test circuit. This eliminates the need to include a fuse in the NAND controller 5, which makes it possible to reduce the chip size and save the effort of measuring timing characteristics by a test circuit and blowing a fuse.

In addition, by inputting the external clock CLK input into the NAND controller 5 as a reference signal into the timing measuring circuit 7, it is possible to use a previously-installed clock terminal without providing a new test-dedicated terminal.

Incidentally, in the foregoing embodiment, it has been described a configuration that the external clock CLK input into the NAND controller 5 is input as a reference signal into the timing measuring circuit 7. Alternatively, the host clock HCLK input into the host 1 may be input as a reference signal into the timing measuring circuit 7.

In addition, in the foregoing embodiment, it has been described a configuration that the timing measuring circuit 7 and the timing adjusting circuit 8 are included in the NAND controller 5. Alternatively, the timing measuring circuit 7 and the timing adjusting circuit 8 may be included in a semiconductor integrated circuit other than the NAND controller 5.

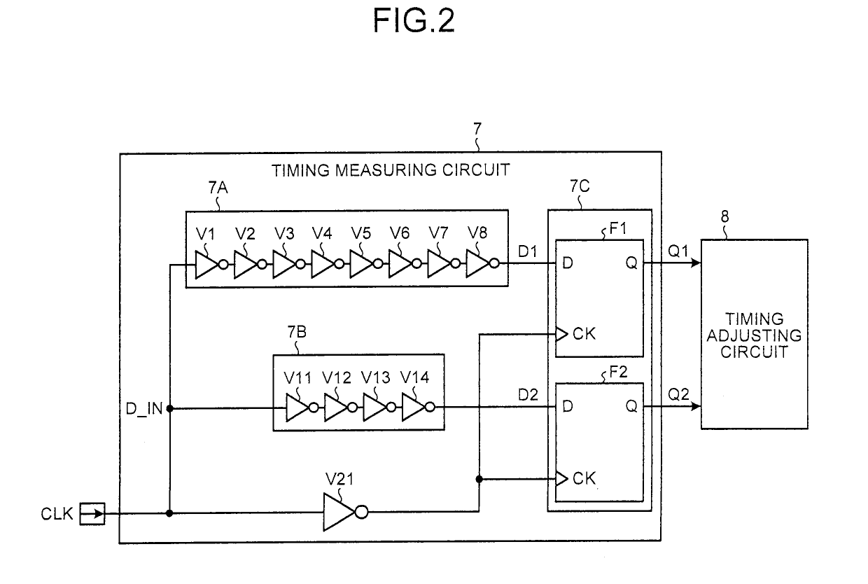

FIG. 2 is a block diagram of a configuration example of the timing measuring circuit according to the first embodiment.

Referring to FIG. 2, the timing measuring circuit 7 includes delay circuits 7A and 7B, and a comparison circuit 7C. The delay circuits 7A and 7B can delay the external clock CLK by different delay times. The delay circuits 7A and 7B may be formed by inverters of one or more stages that are different in number of stages. For example, the delay circuit 7A may be formed by inverters V1 to V8 for eight stages, and the delay circuit 7B may be formed by inverters V11 to V14 for four stages.

The comparison circuit 7C can output two timing adjustment values Q1 and Q2, based on results of comparison between the external clock CLK and two output signals D1 and D2 from the delay circuits 7A and 7B. The comparison circuit 7C is provided with flip-flops F1 and F2 corresponding to the delay circuits 7A and 7B, respectively. Each of the flip-flops F1 and F2 includes a data input terminal D, a clock terminal CK, and an output terminal Q.

Then, the external clock CLK is input as an input signal D_IN to the delay circuits 7A and 7B. Subsequently, the output signals D1 and D2 from the delay circuits 7A and 7B are input into the data input terminals D of the flip-flops F1 and F2, respectively. In addition, the external clock CLK is also input as an input signal D_IN to the clock terminals CK of the flip-flops F1 and F2 via an inverter V21. Incidentally, the inverter V21 can set a drive power such that no delay occurs in the input signal D_IN.

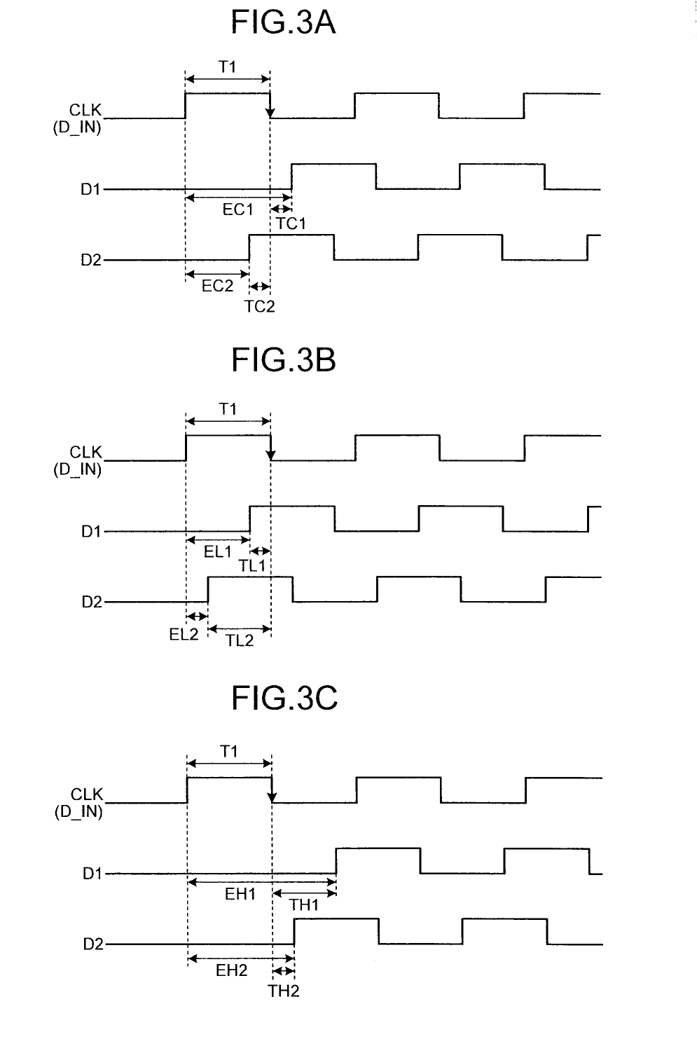

FIG. 3A is a timing chart illustrating operations of the timing measuring circuit under a center condition, FIG. 3B is a timing chart illustrating operations of the timing measuring circuit under a fast condition, and FIG. 3C is a timing chart illustrating operations of the timing measuring circuit under a slow condition. Then, center condition CC, fast condition LL, and slow condition HH refer to conditions under which threshold value Vth for transistors (PMOS transistor and NMOS transistor) for use in the NAND controller 5 shifts from a design value due to manufacturing variations. The center condition CC indicates the case where the threshold value Vth for transistors does not shift from the design value by a predetermined value or more, the fast condition LL indicates the case where the threshold value Vth for transistors is lower than the design value by the predetermined value or more, and the slow condition HH indicates the case where the threshold value Vth for transistors is higher than the design value by the predetermined value or more. In other words, under the fast condition LL, the transistors offer large drive performance and change an output voltage at a high speed, and under the slow condition HH, the transistors offer small drive performance and change an output voltage at a low speed. Under the center condition CC, the drive performance of the transistors resides between those under the fast condition LL and the slow condition HH.

The manufacturing variations occur in the same manner on the same semiconductor substrate. Accordingly, the transistor constituting the delay circuits 7A and 7B and the transistor constituting other circuits of the NAND controller 5 formed on the same semiconductor substrate as that of the delay circuits 7A and 7B are under the same condition out of the center condition CC, fast condition LL, and slow condition HH. By measuring delay times of the delay circuits 7A and 7B, it is possible to know under which condition the transistor in the NAND controller 5 is.

Referring to FIG. 3A, under the center condition CC, when the external clock CLK rises, the output signal D1 rises after a delay time EC1, and the output signal D2 rises after a delay time EC2. In this case, the output signal D1 rises after a delay of a time TC1 from falling edge of the external clock CLK, and the output signal D2 rises a time TC2 ahead of the falling edge of the external clock CLK. Thus, at the falling edge of the external clock CLK, the output signals D1 and D2 become L and H, and the timing adjustment values Q1 and Q2 become L and H. For example, when a pulse width T1 of the external clock CLK is 5 ns, the times TC1 and TC2 can be set to 1 ns. That is, under the center condition CC, when T1=5 ns, the delay times EC1 and EC2 can be set to less than ±5 ns with respect to the falling edge of the external clock CLK. Specifically, while altering the number of stages in the inverters constituting the delay circuits 7A and 7B and the size of the transistor and the like, the delay times EC1 and EC2 are calculated under the center condition CC, and the delay circuits 7A and 7B are designed such that the timing adjustment values Q1 and Q2 become L and H under the center condition CC.

Referring to FIG. 3B, under the fast condition LL, when the external clock CLK rises, the output signal D1 rises after a delay time EL1, and the output signal D2 rises after a delay time EL2. In this case, the output signal D1 rises a time TL1 ahead of the falling edge of the external clock CLK, and the output signal D2 rises a time TL2 ahead of the falling edge of the external clock CLK. Thus, at the falling edge of the external clock CLK, the output signals D1 and D2 become H and H, and the timing adjustment values Q1 and Q2 become H and H.

Referring to FIG. 3C, under the slow condition HH, when the external clock CLK rises, the output signal D1 rises after a delay time EH1, and the output signal D2 rises after a delay time EH2. In this case, the output signal D1 rises after a delay of a time TH1 from the falling edge of the external clock CLK, and the output signal D2 rises after a delay of a time TH2 from the falling edge of the external clock CLK. Thus, at the falling edge of the external clock CLK, the output signals D1 and D2 become L and L, and the timing adjustment values Q1 and Q2 become L and L.

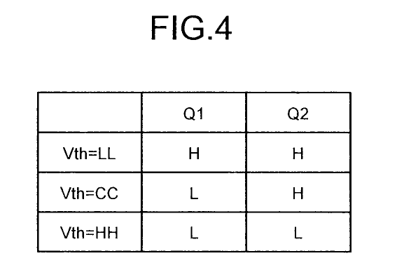

FIG. 4 is a diagram of a truth-value table of outputs from the timing measuring circuit illustrated in FIG. 2.

Referring to FIG. 4, under the center condition CC, the timing adjustment values Q1 and Q2 become L and H. Under the fast condition LL, the timing adjustment values Q1 and Q2 become H and H. Under the slow condition HH, the timing adjustment values Q1 and Q2 become L and L. Thus, variations in operation timing due to manufacturing variations can be reflected in the timing adjustment values Q1 and Q2. As a result, by making timing adjustments based on the timing adjustment values Q1 and Q2, it is possible to correct variations in operation timing due to manufacturing variations.

Incidentally, in the foregoing embodiment, it has been specifically described a configuration that the two delay circuits 7A and 7B are provided to delay the external clock CLK with different delay times, and the comparison circuit 7C is provided to output the two timing adjustment values Q1 and Q2 based on results of comparison between the external clock CLK and the two output signals D1 and D2 from the delay circuits 7A and 7B. In general, N (N is an integer of 1 or more) delay circuit(s) may be provided to delay the external clock CLK with different delay times, and a comparison circuit may be provided to output N timing adjustment values based on results of comparison between the external clock CLK and N output signals from the delay circuits.

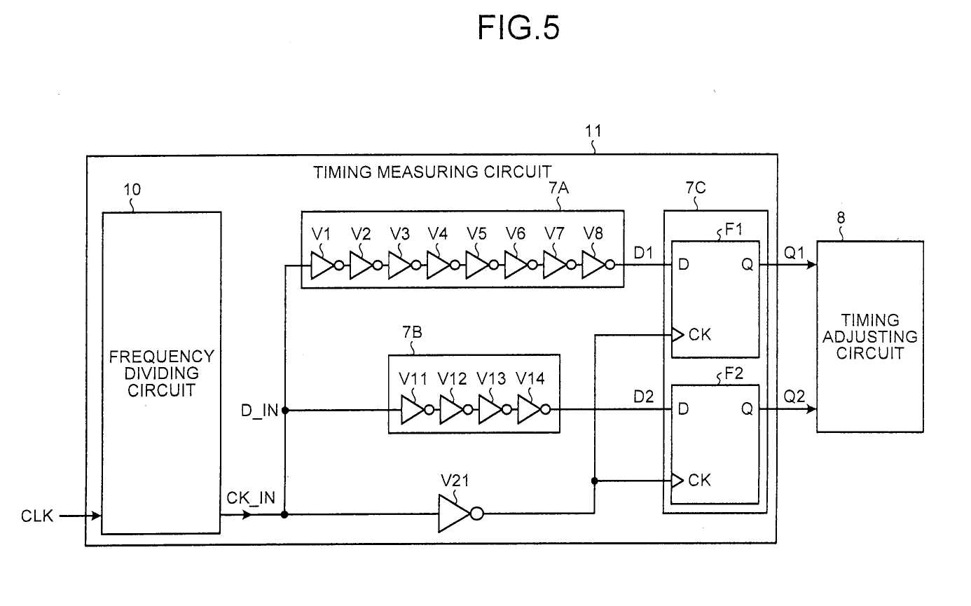

FIG. 5 is a block diagram of a configuration example of a timing measuring circuit according to a second embodiment.

Referring to FIG. 5, in the timing measuring circuit, a frequency dividing circuit 10 is added to the configuration illustrated in FIG. 2. The frequency dividing circuit 10 can divide frequency of the external clock CLK to generate an input signal CK_IN, and input the same into the delay circuits 7A and 7B and the inverter V21. For example, when the external clock CLK operates at 100 MHz, the frequency dividing circuit 10 can divide the frequency of the external clock CLK to generate the input signal CK_IN of 10 MHz.

Here, by providing the frequency dividing circuit 10, even when the frequency of the external clock CLK is high, it is possible to avoid that the times TC1, TL1, TH1, TC2, TL2, and TH2 become extremely short and prevent false operations of the flip-flops F1 and F2.

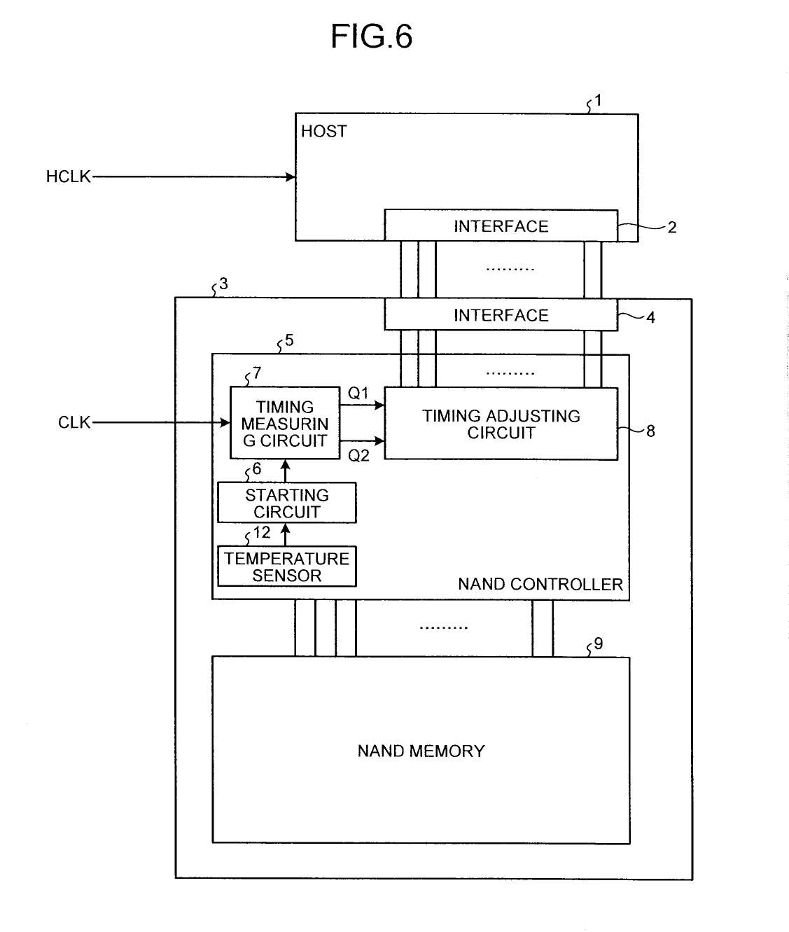

FIG. 6 is a block diagram of a memory system configuration to which a timing measuring circuit according to a third embodiment is applied.

Referring to FIG. 6, a temperature sensor 12 is added to the NAND controller 5 illustrated in FIG. 1. The temperature sensor 12 can measure the temperature of the NAND controller 5. The starting circuit 6 can start the timing measuring circuit 7 based on results of measurement by the temperature sensor 12 during operation of the NAND controller 5. In this case, even when the operation timing fluctuates depending on temperature characteristics of the NAND controller 5, the fluctuations in operation timing are reflected in the delay times of the delay circuits 7A and 7B illustrated in FIG. 2. Accordingly, it is possible to reflect the temperature characteristics of the NAND controller 5 in the timing adjustment values Q1 and Q2 output to the timing adjusting circuit 8. Thus, even when the operation timing fluctuates depending on the temperature characteristics of the NAND controller 5, it is possible to compensate for the fluctuations in the operation timing.

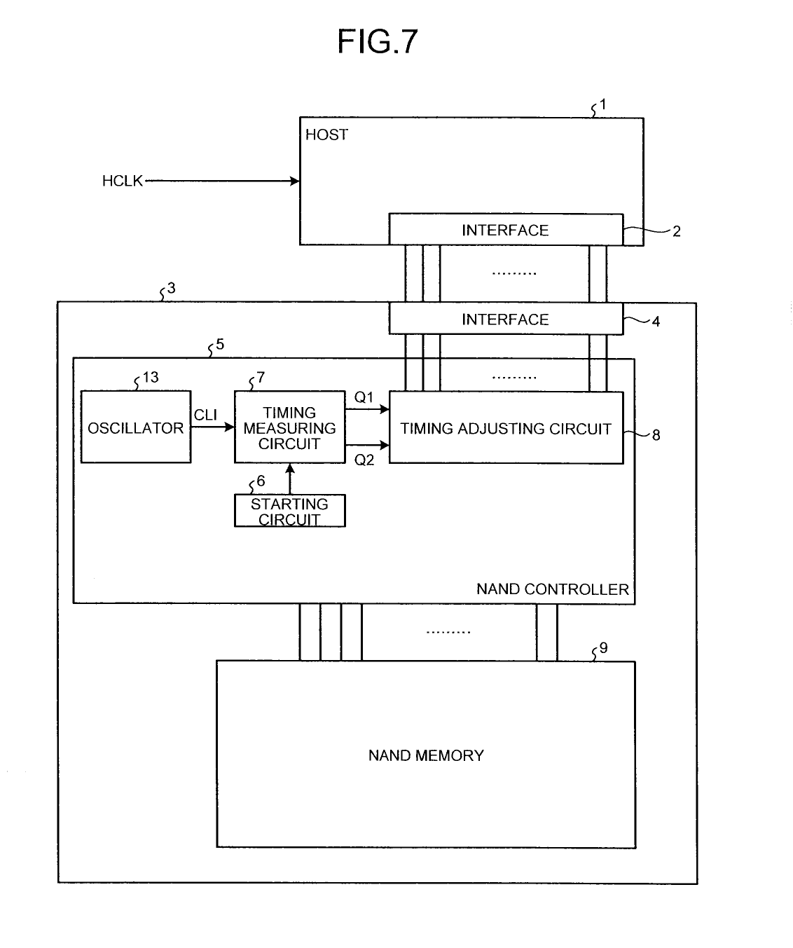

FIG. 7 is a block diagram of a memory system configuration to which a timing measuring circuit according to a fourth embodiment is applied.

Referring to FIG. 7, an oscillator 13 is added to the NAND controller 5 illustrated in FIG. 1. An internal clock CLI generated by the oscillator 13 is input as a reference signal into the timing measuring circuit 7. The timing measuring circuit 7 can generate the timing adjustment values Q1 and Q2 based on the delay time of the internal clock CLI.

The oscillation frequency of the internal clock CLI can be set arbitrarily and separately from the external clock CLK. For example, the frequency of the external clock CLK can be set to 100 MHz, and the frequency of the internal clock CLI can be set to 1 MHz. Accordingly, by using the internal clock CLI as a reference signal of the timing measuring circuit 7, it is possible to set properly the times TC1, TL1, TH1, TC2, TL2, and TH2, and operate properly the flip-flops F1 and F2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A timing measuring circuit, comprising:
N (N is an integer of 2 or more) delay circuits that delay a reference signal by different delay times; and
a comparison circuit that outputs N timing adjustment values based on results of comparison between the reference signal and N output signals from the delay circuits.

2. The timing measuring circuit according to claim 1, wherein the N delay circuits are inverters of one or more stages that are different in number of stages.

3. The timing measuring circuit according to claim 1, wherein the comparison circuit is N flip-flops that are provided corresponding to the N delay circuits, respectively.

4. The timing measuring circuit according to claim 1, wherein the reference signal is an external clock.

5. The timing measuring circuit according to claim 4, comprising a frequency dividing circuit that is provided at a stage prior to the delay circuits to divide frequency of the external clock.

6. The timing measuring circuit according to claim 1, wherein the reference signal is an internal clock.

7. The timing measuring circuit according to claim 1, wherein the N delay circuits output the N timing adjustment values based on a difference between rising time or falling time of the reference signal and rising time or falling time of N output signals from the delay circuits.

8. The timing measuring circuit according to claim 1, wherein the timing measuring circuit is embedded in a semiconductor integrated circuit.

9. The timing measuring circuit according to claim 8, wherein the timing measuring circuit is started at startup of the semiconductor integrated circuit.

10. The timing measuring circuit according to claim 8, wherein the timing measuring circuit is started on a regular basis at startup of the semiconductor integrated circuit.

11. The timing measuring circuit according to claim 8, wherein the timing measuring circuit is started on the basis of an operating temperature of the semiconductor integrated circuit.

12. The timing measuring circuit according to claim 8, wherein the semiconductor integrated circuit includes a timing adjusting circuit that makes timing adjustments based on the N timing adjustment values.

13. The timing measuring circuit according to claim 12, wherein the semiconductor integrated circuit is an NAND controller.

14. The timing measuring circuit according to claim 13, wherein the timing adjusting circuit makes timing adjustments to a data signal and a data strobe signal from the NAND controller.

15. A timing measuring circuit, comprising:
a first delay circuit that delays a reference signal by a first delay time;
a second delay circuit that delays the reference signal by a second delay time different from the first delay time;
a first flip-flop in which an output signal from the first delay circuit is input into a data input terminal and the reference signal is input into a clock terminal; and
a second flip-flop in which an output signal from the second delay circuit is input into a data input terminal and the reference signal is input into a clock terminal.

16. The timing measuring circuit according to claim 15, wherein
the first delay circuit includes at least one inverter of A (A is a positive integer) stages, and
the second delay circuit includes at least one inverter of B (B is a positive integer different from A) stages.

17. The timing measuring circuit according to claim 15, wherein the timing measuring circuit is embedded in a semiconductor integrated circuit.

18. The timing measuring circuit according to claim 17, wherein the timing measuring circuit is started at startup of the semiconductor integrated circuit.

19. The timing measuring circuit according to claim 17, wherein the timing measuring circuit is started on a regular basis at startup of the semiconductor integrated circuit.

20. The timing measuring circuit according to claim 17, wherein the timing measuring circuit is started on the basis of an operating temperature of the semiconductor integrated circuit.
